(19) United States
(12) Patent Application Publication
(10) Pub. No.: US 2015/0060254 A1
(43) Pub. Date: Mar. 5, 2015

(54) TOUCH PANEL AND MANUFACTURING METHOD THEREOF

(71) Applicant: WINTEK CORPORATION, Taichung City (TW)

(72) Inventors: Cheng-Chieh Huang, Yilan City (TW); Kuo-Hsing Chen, New Taipei City (TW); Chung-Hsien Li, Taichung City (TW); Kuo-Chang Su, Taichung City (TW); Chun-Cheng Lu, Taichung City (TW); Chen-Hao Su, Taichung City (TW); Yu-Ting Chen, Pingzhen City (TW)

(21) Appl. No.: 14/472,543

(22) Filed: Aug. 29, 2014

(30) Foreign Application Priority Data
Aug. 30, 2013 (TW) 102131385

(51) Int. Cl. H03K 17/96

(52) U.S. Cl. CPC H03K 17/9622; H03K 2217/960755; H03K 2017/9615
USPC 200/5 R; 29/825

(57) ABSTRACT

A touch panel and a manufacturing method thereof are provided. The touch panel includes an insulating layer, a plurality of first conductive electrodes, a plurality of second conductive electrodes, a plurality of first auxiliary electrodes and a plurality of second auxiliary electrodes. The insulating layer has a plurality of through holes. The first conductive electrodes are arranged along a first direction and electrically connected with each other. The second conductive electrodes are arranged along a second direction and electrically connected with each other. The first auxiliary electrodes and the first conductive electrodes are electrically connected via part of the though holes. The second auxiliary electrodes and the second conductive electrodes are electrically connected via another of the though holes.

This application claims the benefit of Taiwan application Serial No. 102131385, filed Aug. 30, 2013, the subject matter of which is incorporated herein by reference.

### BACKGROUND

1. Technical Field

The disclosure relates in general to a panel and a manufacturing method thereof, and more particularly to a touch panel and a manufacturing method thereof.

2. Description of the Related Art

As the development of the technology, varied inputting devices have been invented. For example, touch panels, handwriting panels, voice inputting devices, and gesture inputting devices are significantly developed on technology.

The touch panel can receive a touching signal from a finger or a stylus to generate a corresponding inputting signal. The touch panel can be configured to a display panel for a user to click or draw on patterns intuitively. Therefore, the touch panel has been widely used in varied electronic devices.

### SUMMARY

The disclosure is directed to a touch panel and a manufacturing method thereof. Conductive electrodes and auxiliary electrodes are used for reducing the impedance of the touch panel and keeping the capacitance difference at a particular level, such that the touching efficiency can be improved.

According to a first aspect of the present disclosure, a touch panel is provided. The touch panel includes an insulating layer, a plurality of first conductive electrodes, a plurality of second conductive electrodes, a plurality of first auxiliary electrodes and a plurality of second auxiliary electrodes. The insulating layer has a first side, a second side opposite to the first side and a plurality of through holes. The first conductive electrodes are disposed on the first side of the insulating layer. The first conductive electrodes are arranged along a first direction and electrically connected with each other. The second conductive electrodes are disposed on the second side of the insulating layer. The second conductive electrodes are arranged along a second direction and electrically connected with each other. The first auxiliary electrodes are disposed on the second side of the insulating layer. The first auxiliary electrodes and the first conductive electrodes are electrically connected via part of the though holes. The second auxiliary electrodes are disposed on the first side of the insulating layer. The second auxiliary electrodes and the second conductive electrodes are electrically connected via another part of the though holes.

According to a second aspect of the present disclosure, a manufacturing method of a touch panel is provided. The manufacturing method of the touch panel includes the following steps. A plurality of first conductive electrodes and a plurality of second auxiliary electrodes are formed. The first conductive electrodes are arranged along a first direction and electrically connected with each other. An insulating layer is formed on the first conductive electrodes and the second auxiliary electrodes. The insulating layer has a plurality of through holes. A plurality of second conductive electrodes and a plurality of first auxiliary electrodes are formed on the insulating layer. The second conductive electrodes are arranged along a second direction and electrically connected with each other. The first auxiliary electrodes and the first conductive electrodes are electrically connected via part of the through holes. The second auxiliary electrodes and the second conductive electrodes are electrically connected via another part of the through holes.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 is a top view of a touch panel.

FIGS. 2A to 2C illustrate a flow chart of a manufacturing method of the touch panel of FIG. 1.

FIG. 3 is a cross-sectional view of the touch panel of FIG. 1 along a cutting line 3-3.

FIG. 4 is a cross-sectional view of the touch panel of FIG. 1 along a cutting line 4-4.

FIGS. 5A to 5E show several embodiments of a plurality of first connecters and a plurality of second connecters of FIG. 1.

FIGS. 6A to 11B illustrate an experimental records of the impedance and the power loss according to different ratios of the cross-section of a plurality of connecters to that of the conductive electrodes.

### DETAILED DESCRIPTION

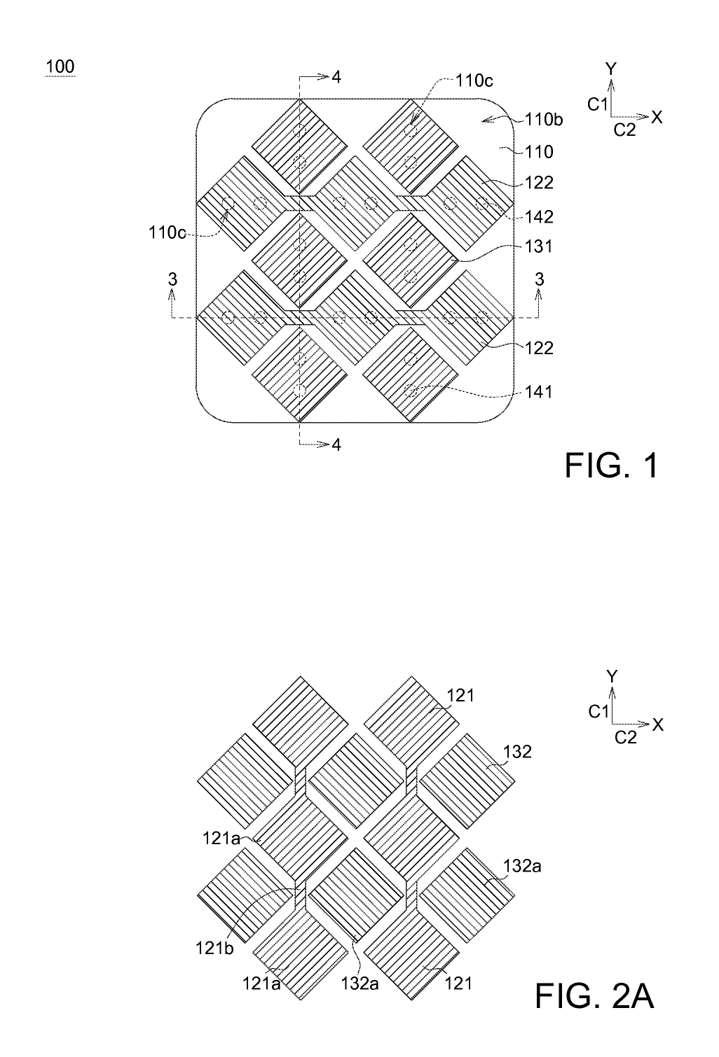

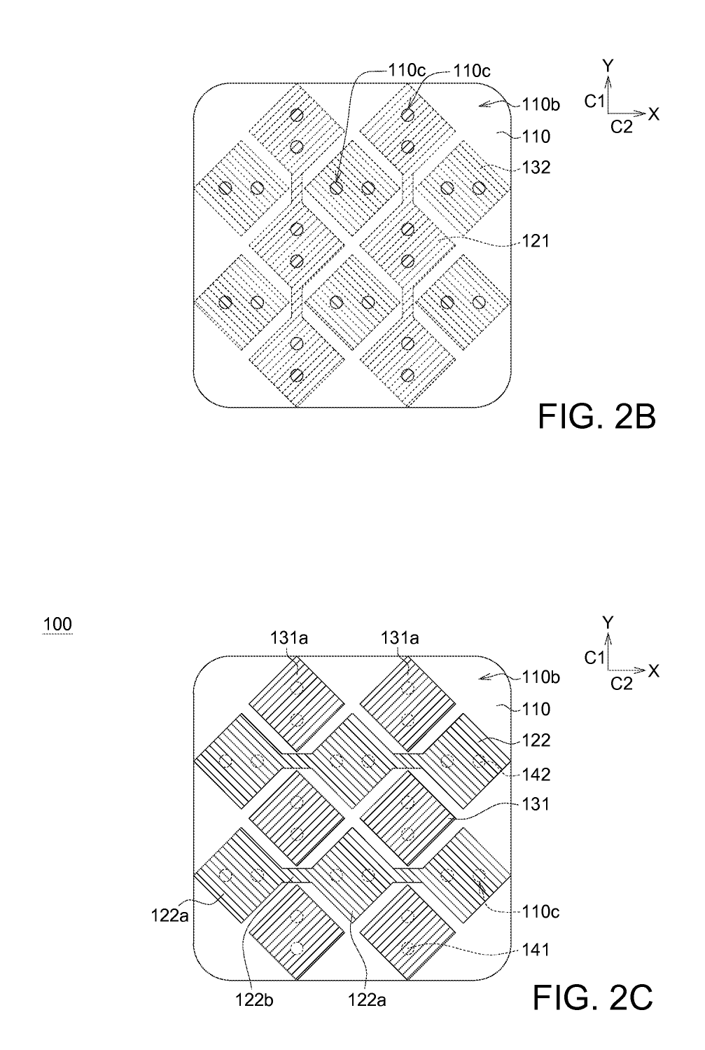

Please referring to FIGS. 1 and 2A to 2C, FIG. 1 is a top view of a touch panel 100 and FIGS. 2A to 2C illustrate a flow chart of a manufacturing method of the touch panel 100 of FIG. 1. To simplify the description, the following description is focused on some elements of the touch panel 100 relating to the present invention, other elements, such as substrate and/or cover lens are not illustrated in the drawings. However, it should be understood that the substrate of the present invention includes a substrate separated from a display device or a substrate integrated within a display device, such as a color filter substrate of a liquid crystal display or an encapsulation plate of an organic light-emitting diodes display device. Moreover, the substrate or the cover lens can be covered with a patterned decoration layer having patterns, symbols or text. The touch panel 100 includes an insulating layer 110, a plurality of first conductive electrodes 121, a plurality of second conductive electrodes 122, a plurality of first auxiliary electrodes 131, a plurality of second auxiliary electrodes 132, a plurality of first connecters 141 and a plurality of second connecters 142. Due to the viewing angle, FIG. 1 shows the second conductive electrodes 122, the first auxiliary electrodes 131 and the insulating layer 110 by solid lines and shows the first connecters 141 and the second connecters 142 by dashed lines. The first conductive electrodes 121 and the second auxiliary electrodes 132 are hided and are not shown in the FIG. 1.

The first conductive electrodes 121 and the second auxiliary electrodes 132 are disposed on a first side 110a of the insulating layer 110, such as the bottom surface of the insulating layer 110. The second conductive electrodes 122 and the first auxiliary electrodes 131 are disposed on the second side 110b of the insulating layer 110, such as the top surface of the insulating layer 110. The insulating layer 110 has a plurality of through holes 110c. The first connecters 141 are disposed in part of the through holes 110c for electrically connecting the first conductive electrodes 121 and the first auxiliary electrodes 131. The second connecters 142 are disposed in another part of the through holes 110c for electrically connecting the second conductive electrodes 122 and the second auxiliary electrodes 132.

The stacking relationship among those elements can be illustrated via the manufacturing method of the touch panel 110. Please referring to

FIG. 2A, firstly, a plurality of first conductive electrodes 121 and a plurality of second auxiliary electrodes 132 are formed on the substrate. The first conductive electrodes 121 are electrically connected and arranged along a first direction C1, such as Y axis, to form a plurality of strip structures. The second auxiliary electrodes 132 are arranged alone a second direction C2, such as X axis, and are separated. The first conductive electrodes 121 and the second auxiliary electrodes 132 are arranged in a matrix, and the first conductive electrodes 121 and the second auxiliary electrodes 132 are interlaced and are not located at the same row or the same column.

Then, please referring to FIG. 2B, the insulating layer 110 is formed on the first conductive electrodes 121 and the second auxiliary electrodes 132, and covers the substrate. Because the first conductive electrodes 121 and the second auxiliary electrodes 132 are covered by the insulating layer 110, the first conductive electrodes 121 and the second auxiliary electrodes 132 are represented by dashed lines. Afterwards, the through holes 110c are formed on the insulating layer 110. For example, an exposing and patterning process is performed on the locations of the insulating layer 110 corresponding to the first conductive electrodes 121 and the second auxiliary electrodes 132 to form the through holes 110c. The drawings are exemplified with two through holes 110c corresponding to each first conductive electrode 121 and each second auxiliary electrode 132, but it is not limited thereto.

Then, please referring to FIG. 2C, the second conductive electrodes 122 and the first auxiliary electrodes 131 are formed on the insulating layer 110. The second conductive electrodes 122 are arranged along the second direction C2 and electrically connected with each other. The first auxiliary electrodes 131 are arranged along the first direction C1 and are separated. The second conductive electrodes 122 and the first auxiliary electrodes 131 are arranged in a matrix, and the second conductive electrodes 122 and the first auxiliary electrodes 131 are interlaced and are not located at the same row or the same column. The second conductive electrodes 122 extend to part of the through holes 110c to form the second connecters 142 for electrically connecting the second auxiliary electrodes 132 (shown in FIG. 2A).

The first auxiliary electrodes 131 extend to the part of the through holes 110c to form the first connecters 141 for electrically connecting the first conductive electrodes 121 (shown in FIG. 2A).

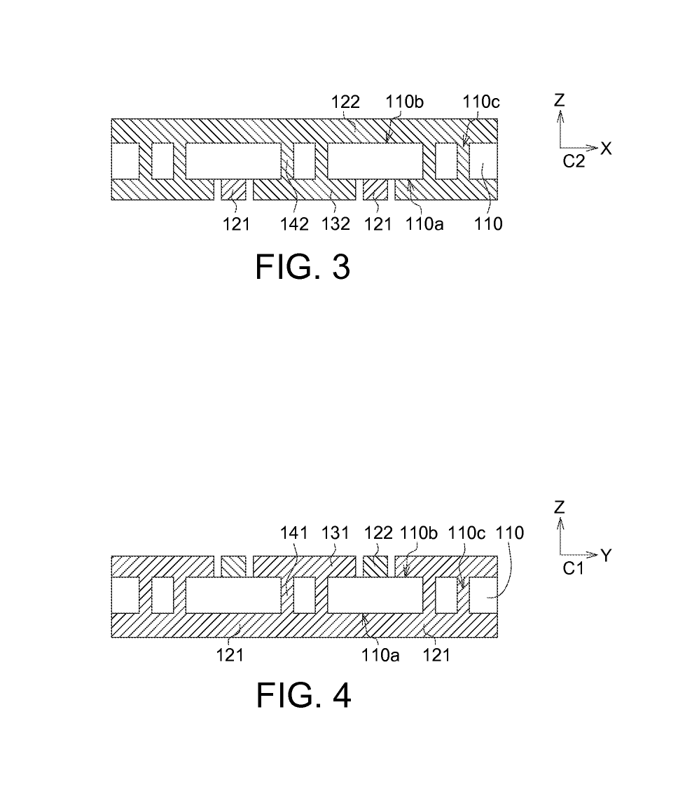

Please referring to FIG. 3, FIG. 3 is a cross-sectional view of the touch panel 100 of FIG. 1 along a cutting line 3-3. The cutting line 3-3 is parallel to the second direction C2. The second conductive electrodes 122 are arranged alone the second direction C2, so the second conductive electrodes 122 is continuously connected in the cross-sectional view along the cutting line 3-3. The first conductive electrodes 121 are arranged alone the first direction C1 and are not arranged alone the second direction C2, so the first conductive electrodes 121 are discontinuous in the cross-sectional view along the cutting line 3-3.

Please referring to FIG. 4, FIG. 4 is a cross-sectional view of the touch panel 100 of FIG. 1 along a cutting line 4-4. The cutting line 4-4 is parallel to the first direction C1. The first conductive electrodes 121 are arranged along the first direction C1, so the first conductive electrodes 121 are continuously connected in the cross-sectional view along the cutting line 4-4. The second conductive electrodes 122 are arranged along the second direction C2 and not arranged along the first direction C1, so the second conductive electrodes 122 are discontinuous in the cross-sectional view along the cutting line 4-4.

As shown in FIG. 2A, regarding the detail structure of the first conductive electrodes 121, the first conductive electrodes 121 are composed of a plurality of first enlarging portions 121a and a plurality of first narrowing portions 121b. Each first narrowing portion 121b connects two adjacent first enlarging portions 121a to from a strip structure.

As shown in FIG. 2C, regarding the detail structure of the first auxiliary electrodes 131, the first auxiliary electrodes 131 are composed of a plurality of second enlarging portions 131a. The first enlarging portions 131a are separated and overlap with the first enlarging portions 121a of the first conductive electrodes 121 (shown in FIG. 2A).

As shown in FIG. 2C, regarding to the detail structure of the second conductive electrodes 122, the second conductive electrodes 122 are composed of a plurality of third enlarging portions 122a and a plurality of second narrowing portions 122b. Each second narrowing portion 122b connects two adjacent second enlarging portions 122a to from a strip structure.

As shown in FIG. 2A, regarding to the detail structure of the second auxiliary electrodes 132, the second auxiliary electrodes 132 are composed of a plurality of fourth enlarging portions 132a. The fourth enlarging portions 132a are separated and overlap with the third enlarging portions 122a of the second conductive electrodes 122 (shown in FIG. 2C).

As shown in FIG. 2C, two second enlarging portions 131a of the first auxiliary electrodes 131 are located at two sides of one second narrowing portion 122b of the second conductive electrodes 122. As shown in FIG. 2A, two fourth enlarging portions 132a of the second auxiliary electrodes 132 are located at two sides of one first narrowing portion 121b of the first conductive electrodes 121.

Moreover, please referring to table 1, a comparison between the capacitance of the touch panel 100 of the present embodiment and that of a touch panel whose two axis transparent sensing elements are disposed at the same side and crossed via bridge structures. As shown in table 1, the touch panel 100 of the present embodiment has low capacitance under touching or not touching, and the difference between the capacitance under touching and the capacitance under not touching is not conspicuously decreased and the detecting function can be kept.

TABLE 1
The comparison between the touch panels

| | | | The touch panel whose two | |
|---|---|---|---|---|
| | | | axis transparent sensing | |
| | | | elements are disposed at the | |
| | The touch panel 100 of the | | same side and crossed via | |
| | present embodiment | | bridge structures | |
| | capacitance | difference | capacitance | Difference |
| Under not | 1.4962 | 0.3237 | 1.9736 | 0.34 |
| touching | | | | |
| Under | 1.1725 | | 1.6263 | |
| touching | | | | |

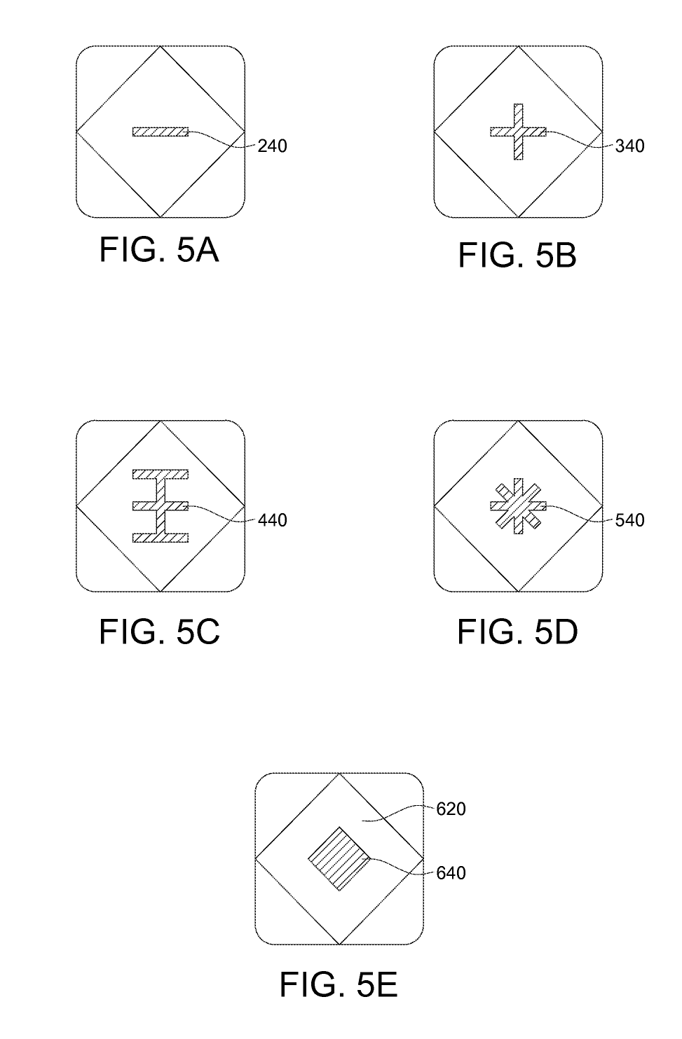

As shown in FIGS. 1 to 4, the shape of the cross-section of the first connecters 141 and the second connecters 142 is exemplified as a circle. In other embodiment, the first connecters 141 and the second connecters 142 can be other shape. Please referring to FIGS. 5A to 5E, FIGS. 5A to 5E show several embodiments of the first connecters 141 and second connecters 142 of FIG. 1. In other embodiment, the shape of the cross-section of the first connecters 141 and the second connecters 142 can be designed as the shape of connecters 240 to 640. As shown in FIG. 5A, the cross-section of the connecter 240 is bar shaped. For example, the extending direction of all connecters 240 can be parallel to the first direction C1 or the second direction C2. Or, the extending direction of some of the connecters 240 can extend toward one direction, and the extending direction of others can extend another direction.

As shown in FIG. 5B, the cross-section of the connecter 340 are cross shaped. For example, two extending directions of one connecter 340 can be parallel to the first direction C1 and the second direction C2 respectively. Or, an included angle between two extending directions of one connecter 340 can be 45 degrees.

As shown in FIG. 5C, the cross-section of the connecter 440 is composed of three parallel bars and one connecting bar connected those parallel bars. For example, the extending direction of the parallel bars and the extending direction of the connecting bar can be parallel to the first direction C1 and the second direction C2 respectively. OR, an included angle between the extending direction of the parallel bars and the extending direction of the connecting bar can be 45 degrees.

As shown in FIG. 5D, the cross-section of the connecter 540 is composed of three bars intersected at the same point. For example, three extending directions can be parallel to the first direction C1, parallel to the second direction C2 and inclined to the first direction C1 with 45 degrees respectively.

As shown in FIG. 5E, the cross-section of the connecter 640 is similar to that of a conductive electrode 620. For example, the connecter 640 and the conductive electrode 620 are rhombus shaped. The four edges of the connecter 640 can be parallel to that of the conductive electrode 620 respectively.

As shown in FIG. 1, the number of the first connecters 141 corresponding to one first conductive electrode 121 and one first auxiliary electrode 131 is two. In other embodiment, the number of the first connecters 141 corresponding to one first conductive electrode 121 and one first auxiliary electrode 131 can be one, two or more than two. Similarly, the number of the second connecters 142 corresponding to one second conductive electrode 122 and one second auxiliary electrode 132 is two. In other embodiment, the number of the second connecters 142 corresponding to one second conductive electrode 122 and one second auxiliary electrode 132 can be one, two or more than two.

The number of the first connecters 141 can be determined according to the ratio of the cross-section of the first connecters 141 to that of the first conductive electrodes 121. Similarly, the number of the second connecters 142 can be determined according to the ratio of the cross-section of the second connecters 142 to that of the second conductive electrodes 122. The power loss affected according to the ratio of the cross-section of the connecter 740 to that of the conductive electrodes 720 is analyzed as below.

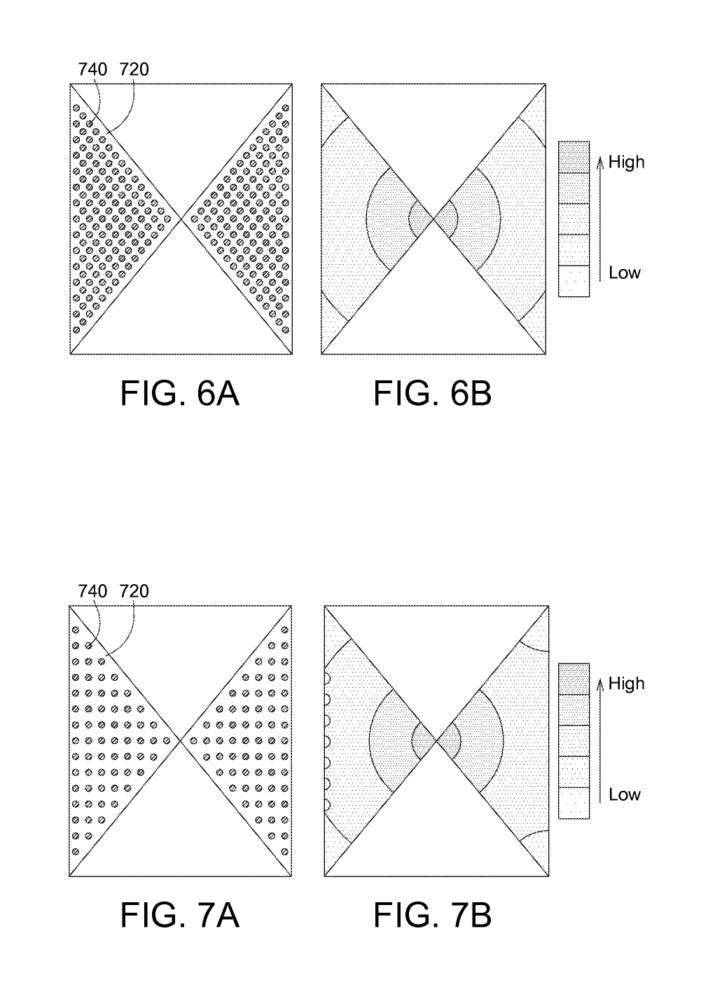

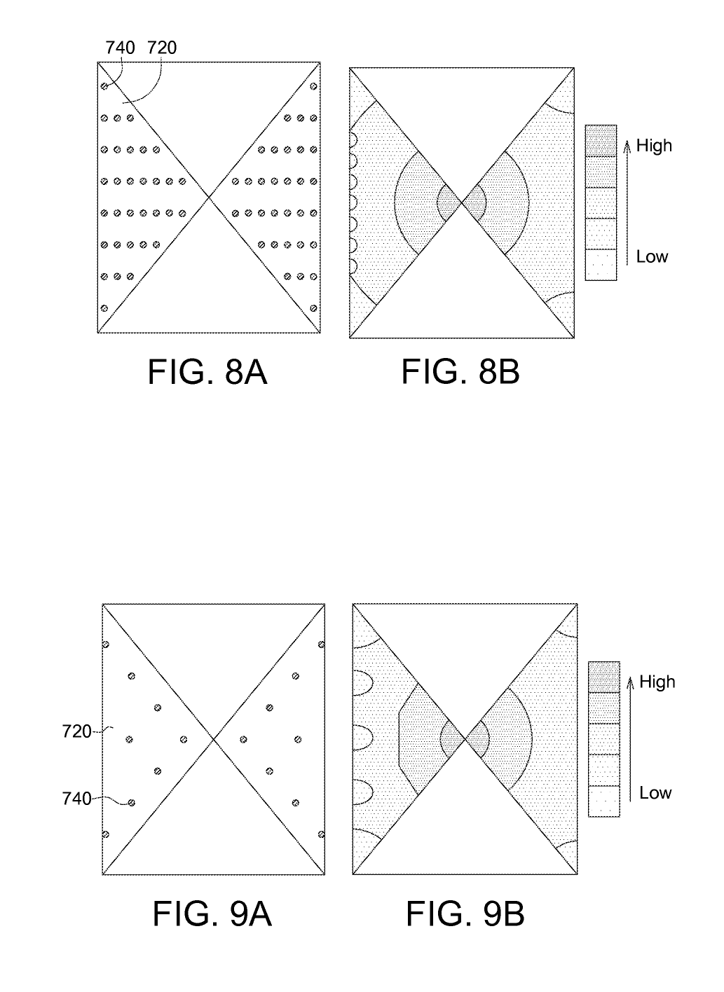

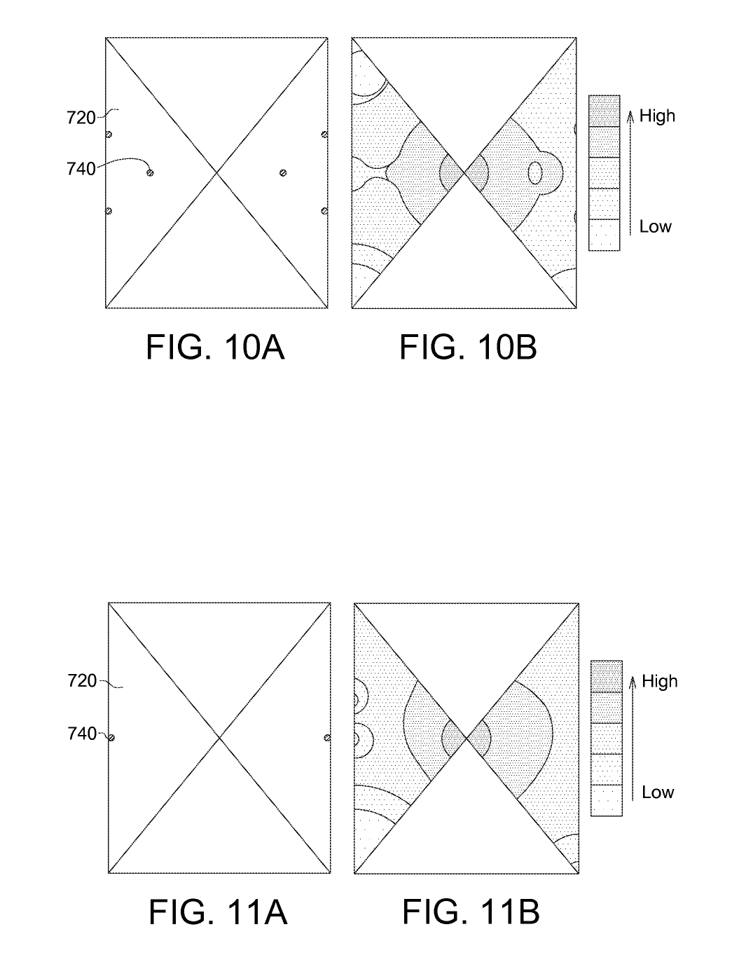

Please referring to FIGS. 6A to 11B, FIGS. 6A to 11B illustrate an experimental records of the impedance and the power loss according to different ratios of the cross-section of the connecters to that of the conductive electrodes. As shown in FIGS. 6A, 7A, 8A, 9A, 10A and 11A, the ratios of cross-section of the connecters 740 to that of the conductive electrodes 720 are 22%, 13%, 6%, 1.3%, 0.4% and 0.2% respectively. The numbers of the connecters 740 are gradually decreased. FIGS. 6B, 7B, 8B, 9B, 10B and 11B illustrate the power loss in FIGS. 6A, 7A, 8A, 9A, 10A and 11A. In FIGS. 6B, 7B, 8B, 9B, 10B and 11B, each contour represents one level of the power loss. The innermost contour represents the highest power loss. If one contour is outer than another counter, then the level of the power loss of this contour is lower than that of the another counter.

As shown in FIGS. 6B, 7B and 8B, the distribution of the power loss is symmetrical and uniform, and the range of high power loss is small. As shown in FIGS. 9B, 10B and 11B, the distribution of the power loss is asymmetry, there are some significant ripples, and the range of high power loss is large.

Moreover, regarding the impedance, the impedances measured in FIGS. 6A, 7A, 8A, 9A, 10A and 11A are 385.48, 386.11, 387.46, 389.41, 393.79 and 398.39 ohm which are gradually increased.

If the ratio of the cross-section of the connecters 740 to that of the conductive electrodes 720 is high, then the distribution of the power loss is symmetrical and uniform, the range of high power loss is small and impedance is small. As shown in the experiment, if the ratio of the cross-section area of the connecters 740 to the area of the conductive electrodes 720 is greater than 6%, then the impedance is reduced to be a particular level and the power loss is improved.

That is to say, the ratio of the cross-section area of the first connecters 141 to the area of the first conductive electrodes 122 can be greater than 6% for reducing the impedance to be a particular level and improving the power loss. Similarly, the ratio of the cross-section area of the second connecters 142 to the area of the second conductive electrodes 122 can be greater than 6% for reducing the impedance to be a particular level and improving the power loss.

In the present embodiment, the area the first conductive electrodes 121 is substantially equal to that of the first auxiliary electrodes 131. The area of the second conductive electrodes 122 is substantially equal to that of the second auxiliary electrodes 132. The first conductive electrodes 121 and the first auxiliary electrodes 131 are fully overlapped.

In another embodiment, the first side 110a of the insulating layer 110 can be a touching side for a finger, the area of the first conductive electrodes 121 can be greater than that of the first auxiliary electrodes 131, and the area of the second auxiliary electrodes 132 can be greater than that of the second conductive electrodes 122.

In another embodiment, the first side 110a of the insulating layer 110 can be a touching side for a finger, the area of the second conductive electrodes 122 can be greater than that of the second auxiliary electrodes 132, and the area of the first auxiliary electrodes 131 can be greater than that of the first conductive electrodes 121.

Moreover, the shape of the first, second conductive electrodes 121, 122 and the shape of the first, second auxiliary electrodes 131, 132 can be different. For example, the first, second conductive electrodes 121, 122 can be rhombus, the first, second auxiliary electrodes 131, 132 can be rectangle, but it is not limited thereto. Further, if a particular shape of one side of the first, second conductive electrodes 121, 122 and the first, second auxiliary electrodes 131, 132 are irregular, then the shape of the another side of the first, second conductive electrodes 121, 122 and the first, second auxiliary electrodes 131, 132 can be complementary to that particular shape. For example, the shape of each side can be a rhombus having a plurality of protruding portions and a plurality of concave portions interlaced with each other, the protruding portions on one side correspond to the concave portions on another side, and the concave portions on one side correspond to the protruding portions on another side, such that the visual effects can be well.

Moreover, as shown in FIG. 1, the first connecters 141 are arranged along the first direction C1, the second connecters 142 are arranged along the second direction C2. That is to say, the first connecters 141 and the first conductive electrodes 121 are arranged along the same direction, and the second connecters 142 and the second conductive electrodes 122 are arranged along the same direction. As a result, the signal transmission capacity of the first conductive electrodes 121 in the first direction C1 can be improved, and the signal transmission capacity of the second conductive electrodes 122 in the second direction C2 can be improved.

In the present embodiment, the material of the first conductive electrodes 121, the material of the second conductive electrodes 122, the material of the first auxiliary electrodes 131, the material of the second auxiliary electrodes 132, the material of the first connecters 141 and the material of the second connecters 142 are the same. The material of the first conductive electrodes 121, the material of the second conductive electrodes 122, the material of first auxiliary electrodes 131, the material of the second auxiliary electrodes 132, the material of the first connecters 141 and the material of the second connecters 142 can be transparent conductive material, such as indium tin oxide (ITO), or carbon nanotubes. The material of the first connecters 141 and the material of the second connecters 142 can be non-transparent conductive material, such as metal or nano-silver wire. If the materials of those elements are the same, then the efficiency of the manufacturing process can be improved. Moreover, the first, second conductive electrodes 121, 122 and the first, second auxiliary electrodes 131, 132 are not limited to be continuous thin films, and they can be mesh, such as metal mesh.

In another embodiment, the material of the first conductive electrodes 121 and the material of the second conductive electrodes 122 can be different. For example, if the touch panel 100 is rectangle shaped instead of square, the material of the first conductive electrodes 121 and the material of the second conductive electrodes 122 can be different to adjust the impedance distribution of the touch panel 100, such that the impedance of the long edge of the touch panel 100 and the impedance of the short edge of the touch panel 100 can be similar.

In another embodiment, the material of the first conductive electrodes 121 and the material of the first auxiliary electrodes 131 can be different, and the material of the second conductive electrodes 122 and the material of the second auxiliary electrodes 132 can be different. For example, the material of the first conductive electrodes 121 and the second conductive electrodes 122 can be a material having low impedance, and the material of the first auxiliary electrodes 131 and the second auxiliary electrodes 132 can be a material having high impedance.

OR, the material of the second conductive electrodes 122 and the first auxiliary electrodes 131 can be a material having low impedance, and the material of the second auxiliary electrodes 132 and the first conductive electrodes 121 can be a material having high impedance.

According to the touch panel 100 and the manufacturing method thereof, the first conductive electrodes 121, the second conductive electrodes 122, the first auxiliary electrodes 131 and the second auxiliary electrodes 132 are used for reducing the impedance of the touch panel 100 and the capacitance difference can be kept to improve the detecting efficiency.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A touch panel, comprising:
an insulating layer having a first side, a second side opposite to the first side and a plurality of through holes;
a plurality of first conductive electrodes disposed on the first side of the insulating layer, the first conductive electrodes being arranged along a first direction and electrically connected with each other;
a plurality of second conductive electrodes disposed on the second side of the insulating layer, the second conductive electrodes being arranged along a second direction and electrically connected with each other;
a plurality of first auxiliary electrodes disposed on the second side of the insulating layer, the first auxiliary electrodes and the first conductive electrodes being electrically connected via part of the though holes; and
a plurality of second auxiliary electrodes disposed on the first side of the insulating layer, the second auxiliary electrodes and the second conductive electrodes being electrically connected via another part of the though holes.

2. The touch panel according to claim 1, wherein the first auxiliary electrodes overlap with the first conductive electrodes, and the second auxiliary electrodes overlap with the second conductive electrodes.

3. The touch panel according to claim 1, wherein the first auxiliary electrodes extend to part of the through holes to form a plurality of first connecters, the first connecters are disposed in the part of the through holes for electrically connecting the first conductive electrodes and the first auxiliary electrodes; the second conductive electrodes extend to another part of the through holes to form a plurality of second connecters, the second connecters are disposed in the another part of the through holes for electrically connecting the second conductive electrodes and the second auxiliary electrodes.

4. The touch panel according to claim 3, wherein a ratio of a cross-section area of the first connecters to an area of the first conductive electrodes is greater than 6%.

5. The touch panel according to claim 3, wherein the number of the first connecters corresponding to one of the first conductive electrodes is more than two.

6. The touch panel according to claim 3, wherein first connecters are arranged along the first direction.

7. The touch panel according to claim 1, wherein a shape of each first conductive electrode is complementary to that of each first auxiliary electrode, and a shape of each second conductive electrode is complementary to that of each second auxiliary electrode.

8. The touch panel according to claim 1, wherein the first conductive electrodes are composed of a plurality of first enlarging portions and a plurality of first narrowing portions, each first narrowing portion connects two adjacent first enlarging portions, the first auxiliary electrodes are composed of a plurality of second enlarging portions, and the second enlarging portions are separated from each other and overlap with the first enlarging portions of the first conductive electrodes.

9. The touch panel according to claim 8, wherein the second conductive electrodes are composed of a plurality of third enlarging portions and a plurality of second narrowing portions, each second narrowing portion connects two adjacent second enlarging portions, the second auxiliary electrodes are composed of a plurality of fourth enlarging portions, the fourth enlarging portions are separated from each other and overlap with the third enlarging portions of the second conductive electrodes.

10. The touch panel according to claim 1, wherein the first side of the insulating layer is a touching side for a finger, an area of the first conductive electrodes is greater than that of the first auxiliary electrodes, and an area of the second auxiliary electrodes is greater than that of the second conductive electrodes.

11. The touch panel according to claim 1, wherein the first side of the insulating layer is a touching side for a finger, an area of the first auxiliary electrodes is greater than that of the first conductive electrodes, an area of the second conductive electrodes is greater than that of the second auxiliary electrodes.

12. The touch panel according to claim 1, wherein a material of the first conductive electrodes and the second auxiliary electrodes is the same as that of the second conductive electrodes and the first auxiliary electrodes.

13. The touch panel according to claim 1, wherein a material of the first conductive electrodes and the second auxiliary electrodes is different from that of the second conductive electrodes and the first auxiliary electrodes.

14. A manufacturing method of a touch panel, comprising:
forming a plurality of first conductive electrodes and a plurality of second auxiliary electrodes, the first conductive electrodes being arranged along a first direction and electrically connected with each other;
forming an insulating layer on the first conductive electrodes and the second auxiliary electrodes, the insulating layer having a plurality of through holes; and
forming a plurality of second conductive electrodes and a plurality of first auxiliary electrodes on the insulating layer, the second conductive electrodes being arranged along a second direction and electrically connected with each other, the first auxiliary electrodes and the first conductive electrodes being electrically connected via part of the through holes, and the second auxiliary electrodes and the second conductive electrodes being electrically connected via another part of the through holes.

15. The manufacturing method of the touch panel according to claim 14, wherein the first auxiliary electrodes overlap with the first conductive electrodes, and the second auxiliary electrodes overlap with the second conductive electrodes.

16. The manufacturing method of the touch panel according to claim 14, wherein the first auxiliary electrodes extend to part of the through holes to form a plurality of first connecters, the first connecters are disposed in the part of the through holes for electrically connecting the first conductive electrodes and the first auxiliary electrodes; the second conductive electrodes extend to another part of the through holes to form a plurality of second connecters, the second connecters are disposed in the another part of the through holes for electrically connecting the second conductive electrodes and the second auxiliary electrodes.

17. The manufacturing method of the touch panel according to claim 16, wherein a ratio of a cross-section area of the first connecters to an area of the first conductive electrodes is greater than 6%.

18. The manufacturing method of the touch panel according to claim 14, wherein a shape of each first conductive electrode is complementary to that of each first auxiliary electrode, and a shape of each second conductive electrode is complementary to that of each second auxiliary electrode.

19. The manufacturing method of the touch panel according to claim 14, wherein the first conductive electrodes are composed of a plurality of first enlarging portions and a plurality of first narrowing portions, each first narrowing portion connects two adjacent first enlarging portions, the first auxiliary electrodes are composed of second enlarging portions, and the second enlarging portions are separated from each other and overlap with the first enlarging portions of the first conductive electrodes.

20. The manufacturing method of the touch panel according to claim 19, wherein the second conductive electrodes are composed of a plurality of third enlarging portions and a plurality of second narrowing portions, each second narrowing portion connects two adjacent second enlarging portions, the second auxiliary electrodes are composed of a plurality of fourth enlarging portions, and the fourth enlarging portions are separated from each other and overlap with the third enlarging portions of the second conductive electrodes.
